(19) United States
(12) Patent Application Publication
(10) Pub. No.: US 2007/0068794 A1
(43) Pub. Date: Mar. 29, 2007

(54) Anode reactive dual magnetron sputtering

(76) Inventors: Barret Lippey, Belmont, MA (US); Lowell Bitter, Boulder, CO (US); Augusto Oscar Kunrath Neto, Golden, CO (US)

Correspondence Address: FISH & RICHARDSON PC, P.O. BOX 1022, MINNEAPOLIS, MN, 55440-1022, US

(21) Appl. No.: 11/234,345

(22) Filed: Sep. 23, 2005

(51) Int. Cl. C23C 14/32; C23C 14/00

(52) U.S. Cl. 204/192.1; 204/298.02

(57) ABSTRACT

A sputtering apparatus of the present invention includes a chamber for containing a plasma. A first and a second target are positioned in the chamber proximate to a substrate. The first and the second targets include at least one type of target material. A power supply is coupled to the first and the second targets. The power supply supplies power to the first and the second targets such that when the first target sputters target material, the second target becomes anodic and when the second target sputters target material, the first target becomes anodic. The sputtering apparatus also includes a reactive source that supplies reactive species proximate to the substrate. The reactive species are supplied in synchronization with the power supplied to the first and the second targets. The reactive species combines with the sputtered target material to generate a sputtered film on the substrate.

### BACKGROUND OF THE INVENTION

Conventional Dual Magnetron Sputtering (DMS) consists of two magnetron cathodes that are in close spatial proximity. A power supply, such as an alternating current (AC) power supply, is generally connected to the magnetron cathode/targets. The DMS system prevents the occurrence of the so-called “disappearing anode” associated with the deposition of insulating films by conventional direct current (DC) single magnetron sputtering. In conventional DC sputtering, the process stability and film quality of the sputtered film can be adversely affected as the target material coats the anode during the sputtering process. The sputtering rate for conventional DC sputtering is generally significantly greater (on the order of thirty percent greater) than the sputtering rate for conventional dual magnetron sputtering.

### SUMMARY OF THE INVENTION

One aspect of the present invention provides improved methods and apparatus for enabling the synchronized action of metal sputtering and reaction with ionized or excited species produced by a second source. The invention can be embodied in a sputtering apparatus. The sputtering apparatus includes a chamber for containing a plasma. A first and a second target are positioned in the chamber proximate to a substrate. The first and the second targets include at least one type of target material. The sputtering apparatus also includes a power supply that is coupled to the first and the second targets. The power supply supplies power to the first and the second targets such that when the first target sputters target material, the second target becomes anodic and when the second target sputters target material, the first target becomes anodic. The sputtering apparatus also includes a reactive source that supplies reactive species proximate to the substrate. The reactive species is supplied in synchronization with the power supplied to the first and the second targets. The reactive species combines with the sputtered target material to generate a sputtered film on the substrate.

In one embodiment, the power supply includes a mode of operation in which the first and the second targets are non-sputtering for a period of time. The power supply can be an alternating current (AC) power supply, a switched direct current (DC) power supply, or a pulsed DC power supply.

The apparatus can further include a controller that controls the synchronization of the reactive source. For example, the controller can control the synchronization of the reactive source and the power supply. In one embodiment, the reactive source includes a pulsed ion source. The reactive source supplies reactive species proximate to the substrate when at least one of the first and the second targets becomes anodic. One of the first and the second targets repels the reactive species when the one of the first and the second targets becomes anodic. The reactive source includes one of an oxygen source, a nitrogen source, and a carbon source, such as methane. The sputtered target material can be partially or completely reacted by the reactive species.

In one embodiment, at least one of the first and the second targets includes target material such as silicon, zirconium, niobium, tantalum, titanium, or aluminum. The plasma can be generated from an argon feed gas. The substrate can be, but is not limited to, a silicon wafer, a lens, a plastic sheet, a glass plate, or a flexible material. In some embodiments, one or more baffles can be placed in various locations in the chamber.

In another aspect, the invention is embodied in a method for sputtering target material. The method includes ionizing a feed gas to generate a plasma proximate to at least one of a first and a second target. The method also includes supplying power to the first and the second targets such that when the first target sputters target material, the second target becomes anodic and when the second target sputters target material, the first target becomes anodic. The method further includes supplying reactive species proximate to a substrate in synchronization with the power supplied to the first and the second targets. The reactive species combine with the sputtered target material to generate a sputtered film on the substrate.

In one embodiment, supplying power to the first and the second targets further includes supplying power such that the first and the second targets are non-sputtering for a period of time. The method can also include supplying the reactive species in a pulsed manner. The method can further include supplying the reactive species proximate to the substrate when at least one of the first and the second targets becomes anodic. The reactive species can include oxygen ions and/or nitrogen ions. The power supplied can include alternating current (AC) power, switched direct current (DC) power, or pulsed DC power.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a block diagram of a prior art drum coater with a dual magnetron sputtering system having an alternating current (AC) power supply.

FIG. 2 illustrates a block diagram of a dual magnetron sputtering system according to one embodiment of the invention.

FIG. 3 illustrates a block diagram of a reactive source that can be used with the dual magnetron sputtering system of FIG. 2.

FIG. 4 illustrates a timing diagram of an alternating current (AC) voltage and a state of a reactive source according to the invention.

FIG. 5 illustrates a timing diagram of a pulsed direct current (DC) voltage and a state of a reactive source according to the invention.

FIG. 6 illustrates a block diagram of a roll coater with a dual magnetron sputtering system according to another embodiment of the invention.

FIG. 7 illustrates a block diagram of a dual magnetron sputtering system according to another embodiment of the invention.

### DETAILED DESCRIPTION

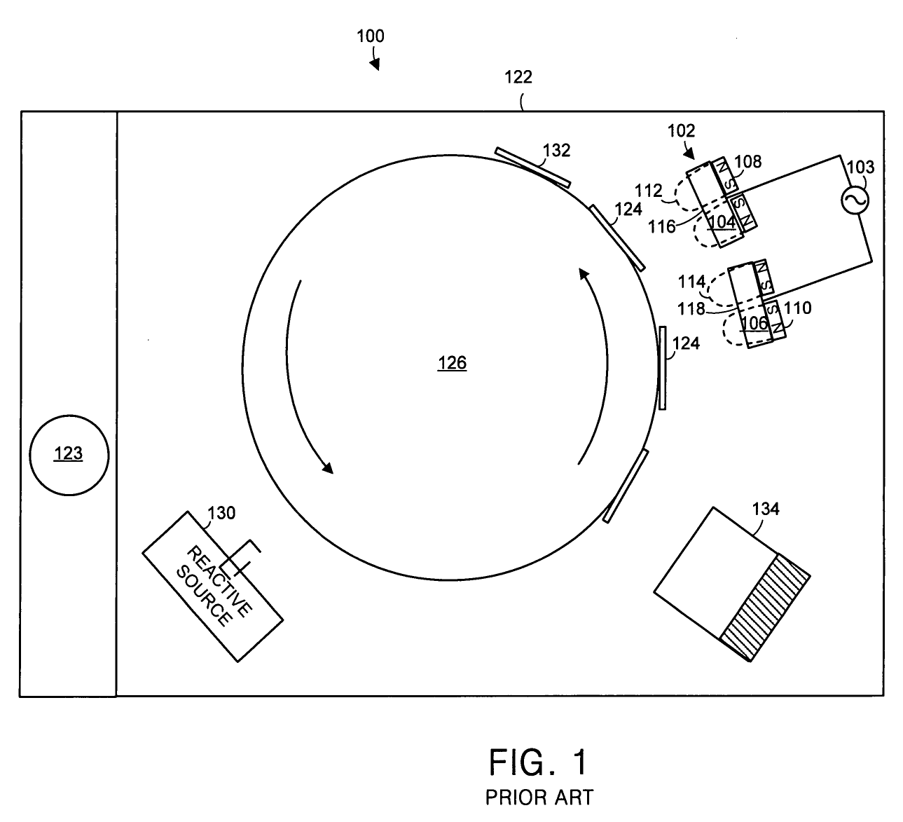

FIG. 1 is a block diagram of a drum coater 100 with a dual magnetron sputtering (DMS) system 102 having an alternating current (AC) power supply 103. Each output of the AC power supply 103 is coupled to a target 104, 106. Each target 104, 106 is backed by a magnet assembly 108, 110, respectively. The magnet assemblies 108, 110 create magnetic fields 112, 114, respectively. The magnetic fields 112, 114 confine plasma proximate to front surfaces 116, 118, of the targets 104, 106, respectively.

A feed gas source (not shown) provides feed gas, typically argon gas to the chamber 122 proximate to the targets 104, 106. A vacuum pump 123 evacuates the chamber 122 to the appropriate pressure. The feed gas is ignited in the sputtering chamber 122 to create a plasma. The AC power supply 103 is used to drive the pair of targets 104, 106. Thus, the targets 104, 106 alternate roles between cathode and anode. For example, when the first target 104 operates as a cathode, the second target 106 operates as its anode. In this phase, the second target 106 (anode) begins to build up a small amount of insulating oxide. In the next phase, the second target 106 operates as the cathode and the first target 104 operates as the anode. In this next phase, the just formed oxide is sputtered from the second target 106, such that a clean anode is maintained to complete the current path between the outputs of the AC power supply 103.

The target material from the targets 104, 106, is sputtered onto a substrate 124 that is mounted to a rotating drum 126. The substrate 124 can be architectural glass, a mirror, a flat panel display, and/or anti-reflection coated glass.

The drum coater 100 also includes a reactive ion source 130. The reactive ion source 130 supplies reactive ions and/or other reactive species to the reactive chamber 130. When a coated substrate 132 is rotated into the path of the reactive source 130, the coating reacts with the reactive species from the reactive source 130 and forms an oxide layer on the substrate 132.

In one embodiment, another source 134 can also be included to deposit material such as silicon on the substrate 124, for example.

Each of the sputtering sources 104, 106, vapor source 134 and the reactive source 130 are activated at an appropriate time as the drum 126 rotates. Each source 104, 106, 134, and 130 operates continuously during successive drum rotations for each film layer. This process can be used to form a film on the substrate 124 having desired characteristics.

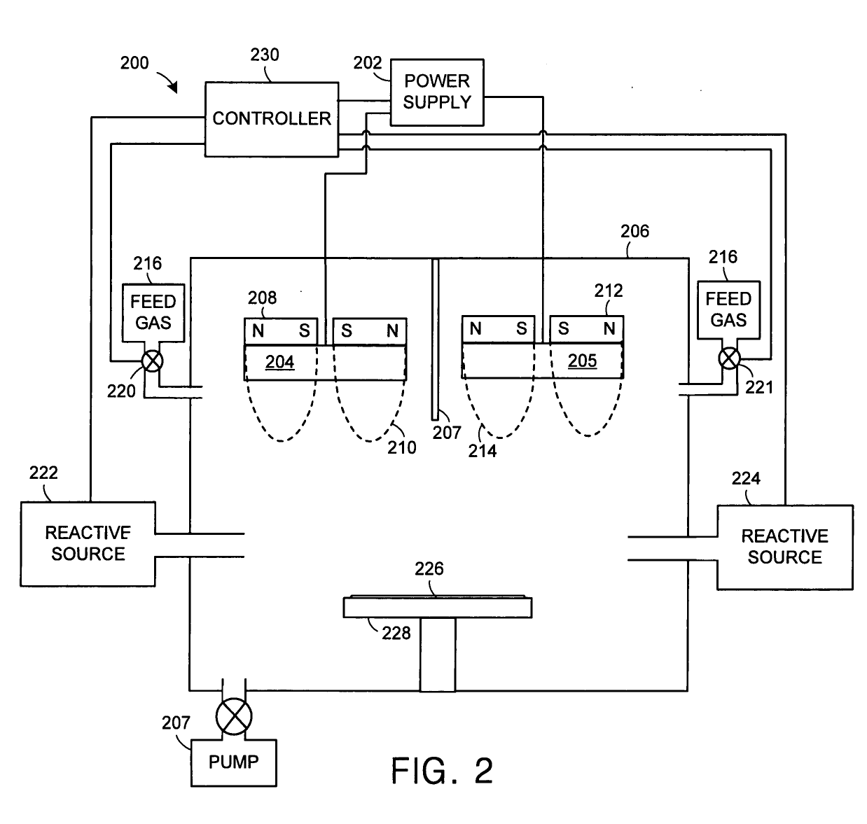

FIG. 2 illustrates a block diagram of a box coater 200 with a dual magnetron sputtering system according to one embodiment of the invention. The box coater 200 includes a power supply 202. The power supply 202 can include an alternating current (AC) power supply, a switched direct current (DC) power supply, or a pulsed DC power supply. Outputs of the power supply 202 are coupled to a first 204 and a second target 205. The first 204 and the second target 205 can be fabricated from silicon, zirconium, niobium, tantalum, titanium, and/or aluminum, for example. The first 204 and the second targets 205 are positioned inside a chamber 206. A vacuum pump 207 maintains the chamber 206 at a desired pressure.

An optional baffle 207 can be positioned at least partially between the first target 204 and the second target 205. The optional baffle 207 helps to sustain a partial pressure gradient in the chamber 206. Additionally, the optional baffle 207 can assist in controlling the electron flow of the plasma. An electrically neutral or floating baffle can be configured to require the electrons in the plasma to travel a longer distance, thus increasing the plasma volume. Other optional baffles (not shown) could also be positioned in the chamber 206.

A first magnet assembly 208 is coupled to the first target 204. The first magnet assembly 208 generates a first magnetic field 210. The first magnetic field 210 has a shape and a strength that confines a plasma proximate to the first target 204. A second magnet assembly 212 is coupled to the second target 205. The second magnet assembly 212 generates a second magnetic field 214. The second magnetic field 214 has a shape and a strength that confines a plasma proximate to the second target 205.

A feed gas source 216 supplies feed gas to the chamber 206 proximate to the targets 204, 205. For example, the feed gas can include argon. The feed gas source 216 can be coupled to valves 220, 221 that precisely meter the feed gas to the chamber 206. For example, the valves 220, 221 can be mass flow controllers. The feed gas source 216 can also include a mixture of gases including one or more inert gases.

The box coater 200 can also include an electron source (not shown) that directs an electron current into the chamber proximate to at least one of the targets 204, 205. For example, the electron source can include a hollow cathode device. The electrons provided by the electron source can increase the intensity of plasma in the chamber.

The box coater 200 can also include one or more reactive sources 222, 224 of reactive species. For example, the reactive sources 222, 224 can be oxygen, nitrogen or a carbon source, such as methane. The reactive sources 222, 224 can be pulsed reactive sources. The reactive sources 222, 224 supply a reactive species, such as reactive ions, proximate to a substrate 226 that is positioned on a pedestal 228. In one embodiment, the reactive sources 222, 224 can be angled towards the substrate 226. Depending on the system configuration, the substrate 226 can include a silicon wafer, a lens, a plastic sheet, a glass plate, or a flexible material, for example. The pedestal 228 can be grounded or biased to a desired voltage. In one embodiment, the pedestal 288 is magnetically biased. The magnetic bias can be arranged to repel hot energetic ions from the substrate 226. Optional baffles (not shown) can be positioned between each reactive source 222, 224 and each respective target 204, 205. Other optional baffles (not shown) can also be positioned between each reactive source 222, 224 and the substrate 226.

A controller 230 controls various components in the box coater 200. The controller 230 can include a processor. For example, the controller 230 can be coupled to the valves 220, 221. In this configuration, the controller 230 can control the feed gas supplied to the chamber 206. The controller 230 can be also coupled to the power supply 202. The controller 230 can control various characteristics of the power supply 202. For example, the controller 230 can control the output voltage, frequency, dwell time, pulse width, etc., of the power supply 202.

The controller 230 can also control the optional electron source (not shown). For example, the controller 230 can vary the voltage, quantity of gas, and other parameters of the electron source to control the electron current emanating from the electron source.

The controller 230 is also coupled to the reactive sources 222, 224. The controller 230 can control the supply of reactive species from the reactive sources 222, 224. For example, the controller 230 can synchronize the supply of reactive species from the reactive sources 222, 224 with the power supplied by power supply 202. In one embodiment, the first reactive source 222 is activated when a negative voltage is supplied to the second target 205 and the second reactive source 224 is activated when a negative voltage is supplied to the first target 204. The negative phase of the voltage is alternately supplied to the first target 204 and the second target 205, thereby causing the first 204 and the second targets 205 to alternately sputter target material. This phase of the target 204, 205 is sometimes referred to as the cathode phase. During the sputtering process, the positively-biased target 204, 205 acts as an anode for the other target 205, 204. This phase of the target 204, 205 is sometimes referred to as the anode phase.

In one embodiment, the reactive sources 222, 224 supply reactive species proximate to the substrate 226. Additionally, as previously described, baffles or movable plates (not shown) can be used to shield one or both of the targets 204, 205 from reactive species during the cathode phase of the process. The reactive sources 222, 224 can be pulsed sources that are activated during the anode phase of the targets 204, 205, respectively.

In one embodiment, the coater 200 operates as follows. The substrate 226 is loaded onto the pedestal 228. The pump 207 creates an appropriate pressure in the chamber 206. The feed gas source 216 provides feed gas to the chamber 206. The flow rate and the volume of the feed gas are controlled by the controller 230. The pump 207 maintains the appropriate pressure in the chamber 206. The power supply 202 supplies a voltage to one of the first 204 and the second targets 205. The voltage is sufficient to create a plasma in the chamber 206. The magnetic fields 210, 214, are designed to confine the plasma proximate to the targets 204, 205. In some embodiments, a separate ionization mechanism is located in the chamber 206 to initiate the plasma.

The power supply 202 is coupled to the targets 204, 205, such that when the first target 204 becomes cathodic, the second target 205 becomes anodic and when the second target 205 becomes cathodic, the first target 204 becomes anodic. The controller 230 controls the characteristics of the power supply 202 including the output current, voltage, phase, polarity, duration, and the synchronization of the power supply 202 with other components in the box coater 200.

The volume of the chamber 206 and/or the distance between the targets 204, 205 can be varied to optimize the sputtering process. For example, if the targets 204, 205 are positioned far enough apart, the electric field between the targets 204, 205 is reduced and the plasma volume is increased. Optimizing the plasma volume can improve both the sputtering rate and the oxidation of the sputtered film. It can also affect the film properties such as the index of refraction and the absorption coefficient.

Each of the targets 204, 205 sputter target material when it is in the cathodic phase. The target material sputter coats the substrate 226. In the anodic phase, each of the targets 204, 205 provides a return path for the electric current generated through the plasma.

The controller 230 also controls the reactive sources 222, 224, such that when the first target 204 becomes anodic, the first reactive source 222 supplies reactive species to the chamber 206. In the anodic phase, the first target 204 repels a portion of the reactive species towards the substrate 226. Specifically, the positively-biased first target 204 repels positively-charged ions and other positively-charged particles in the reactive species.

In the next cycle of the power supply 202, the second target 205 becomes anodic and the second reactive source 224 supplies reactive species to the chamber 206. In the anodic phase, the second target 205 repels a large portion of the reactive species towards the substrate 226.

In one embodiment, the controller 230 synchronizes the process in time as follows. The first target 204 sputters target material which coats the substrate 226 and then the reactive source 222 supplies the reactive species proximate to the substrate 226. The second target 205 then sputters target material and then the reactive source 224 supplies reactive species proximate to the substrate 226. In this embodiment, the target material and the reactive species are alternately provided to the substrate 226. The sputtered target material can be partially or completely reacted by the reactive species.

This cycle continues until a coating having desired characteristics, such as a desired thickness, refractive index, uniformity, homogeneity, etc., is deposited on the substrate 226. Skilled artisans will appreciate that the characteristics of the coating can be modified by adjusting parameters of the power supply 202, the feed gas, the reactive sources 222, 224, the magnetic fields 210, 214, etc.

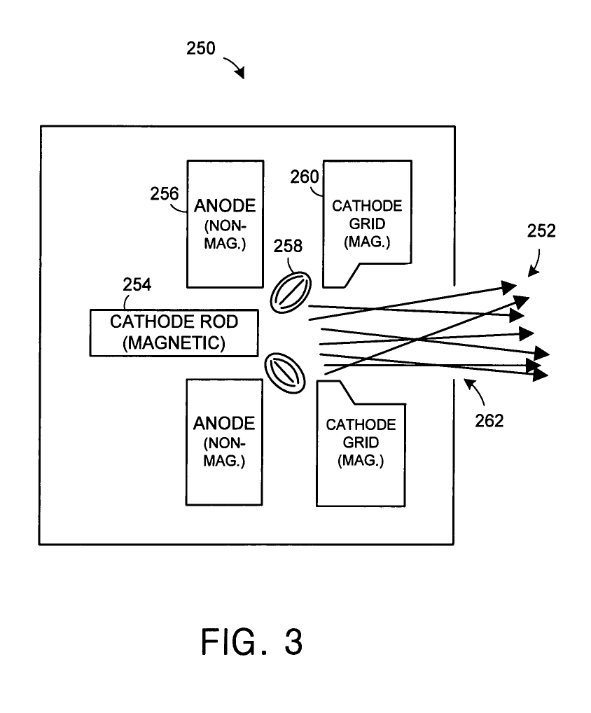

FIG. 3 illustrates a block diagram of a reactive source 250 that can be used with the dual magnetron sputtering system 200 of FIG. 2. In this embodiment, the reactive source 250 is an anode layer-type ion source. Other reactive sources can also be used. The reactive source 250 generates an ion flux 252. In one embodiment, the ions generated by the reactive source 250 have energy that is low enough so as not to sputter the coating from the substrate 226.

The reactive source 250 includes a cathode rod 254 that is at least partially surrounded by an anode 256. The cathode rod 254 can be magnetic and the anode 256 can be non-magnetic. A power supply (not shown) supplies a voltage between the cathode rod 254 and the anode 256. The voltage creates a plasma 258 proximate to the anode 256. Positive ions in the plasma 258 are accelerated towards a negatively-biased cathode-grid 260. Many of the ions are accelerated through the cathode grid 260 and exit through an aperture 262.

The reactive source 250 of FIG. 3 is shown in block form for illustrative purposes. In practice, the reactive source 250 generally includes more components than shown. In some embodiments, a plurality of reactive sources 250 can be joined together to create a multi-cell reactive source (not shown). Other types of reactive ion sources can also be used to produce low energy ions, such as RF sources, End-Hall sources, or Kaufman sources.

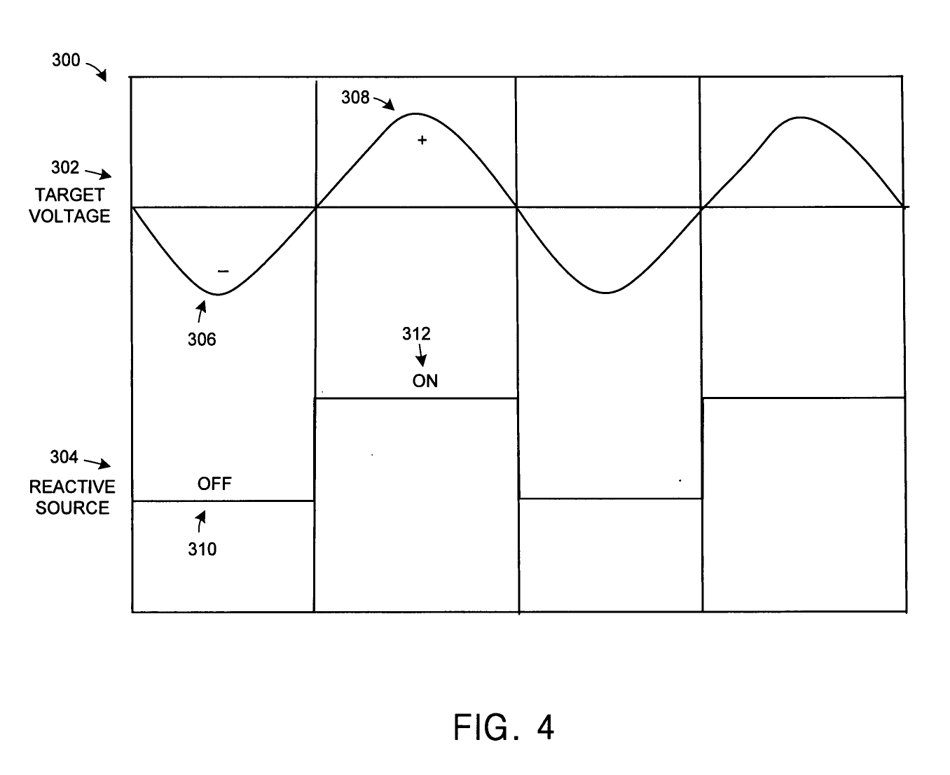

FIG. 4 illustrates a timing diagram 300 of an alternating current (AC) target voltage 302 and a state 304 of a reactive source according to the invention. For example, the frequency of the AC voltage can be between 10 Hz and 20 kHz, but other frequencies can also be used depending on the coating process. The timing diagram 300 is illustrated for one target-reactive source pair.

The AC waveform alternates between a negative voltage 306 and a positive voltage 308. The target sputters target material during the negative voltage phase of the AC waveform. During this negative voltage phase, the reactive source is in the off-state 310. This prevents the negatively-biased target from being poisoned by positive particles in the reactive species that would otherwise be generated by the reactive source.

The sputtering terminates during the positive voltage phase 308 of the AC waveform. The controller sends a signal to activate the reactive source during the positive voltage phase 308 of the AC waveform. The reactive source in the on-state 312 generates reactive species. The positively-biased target repels positively-charged particles in the reactive species towards the substrate 226 (FIG. 2). The reactive species combines with the sputtered target material to create the desired film on the substrate 226.

The AC voltage cycle then repeats. In one embodiment, each target-reactive source pair is operated substantially out-of-phase with the other target-reactive source pair. In other embodiments, the phase between the target-reactive source pairs can be varied depending on the coating process.

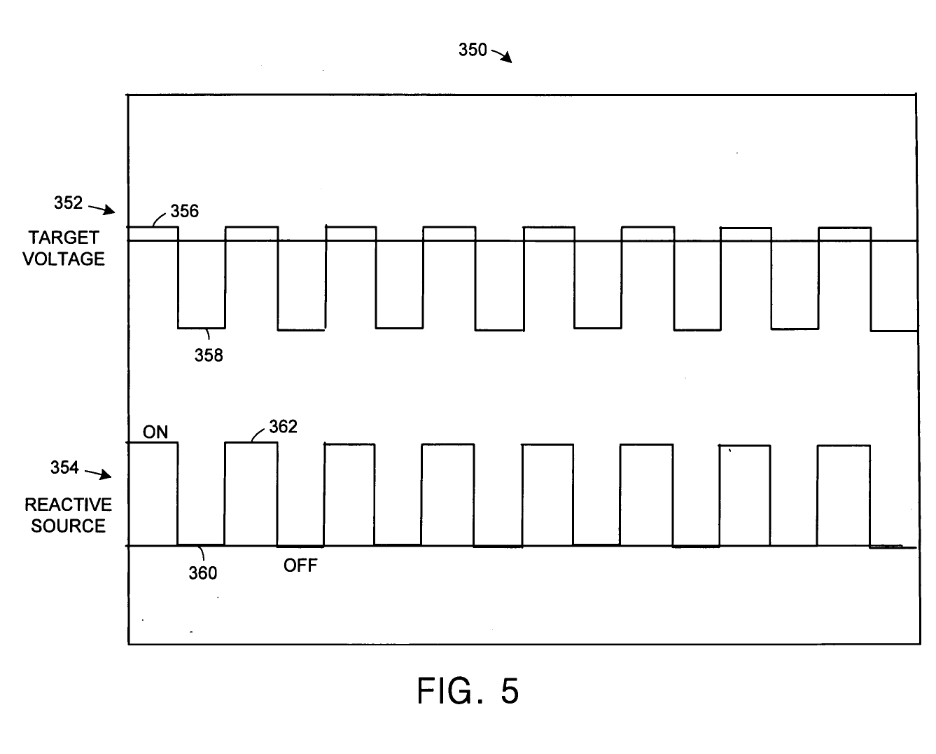

FIG. 5 illustrates a timing diagram 350 of a pulsed direct current (DC) target voltage 352 and a state 354 of a reactive source according to the invention. The timing diagram 350 is illustrated for one target-reactive source pair.

The pulsed DC waveform alternates between a small positive voltage 356 and a negative voltage pulse 358. In one example, the pulsed DC waveform alternates between +40V and −400V. The target sputters target material when the negative voltage pulse 358 is applied. During this negative voltage pulse 358, the reactive source is in the off-state 360.

The sputtering terminates during the small positive voltage phase 356 of the pulsed DC waveform. The reactive source is switched to the on-state 362 during the small positive voltage phase 356 of the pulsed DC waveform. The reactive source in the on-state 362 generates reactive species. The positive voltage repels the positively charged reactive species towards the substrate 226. In addition, the substrate 226 can attract the positive reactive species due to a small negative bias on the substrate 226 from mobile electrons. The reactive species combine with the sputtered target material to create a film on the substrate 226.

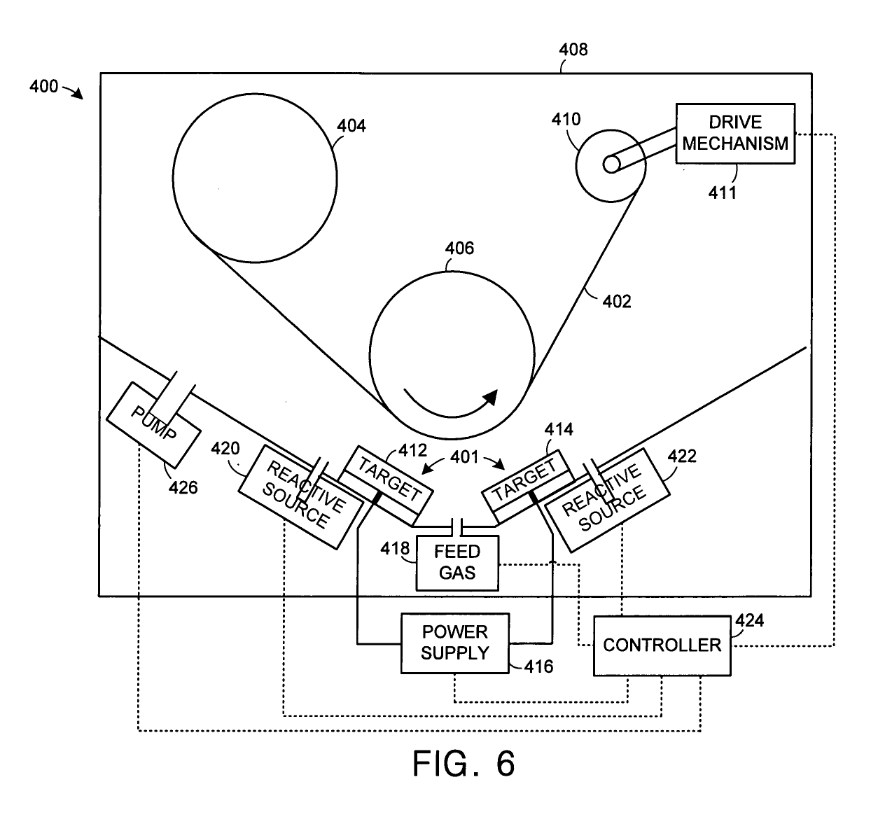

FIG. 6 illustrates a block diagram of a roll coater 400 with a dual magnetron sputtering system 401 according to one embodiment of the invention. In this embodiment, a flexible substrate 402 embodies a belt of flexible material, such as plastic, Mylar, foil, fabric, etc. The substrate 402 can be loaded on a spool 404 and positioned around a drum 406 in the chamber 408. A take-up spool 410 receives the coated portion of the substrate 402. The spool 404, drum 406, and take-up spool 410 can include a drive mechanism 411 that moves the substrate 402 past the targets 412, 414. The drive mechanism 411 can include motors, pulleys, belts, gears, shafts, or any other suitable drive elements.

The roll coater 400 also includes a first target 412 and a second target 414 that are coupled to a power supply 416. A feed gas source 418 provides feed gas proximate to the first 412 and the second targets 414. The power supply 416 supplies a voltage to the first 412 or second target 414 to create a plasma from the feed gas. In other embodiments, a separate ionization system (not shown) can be used to start the plasma.

A first reactive source 420 is positioned proximate to the first target 412. The first reactive source 420 is configured to generate reactive species proximate to the substrate 402 when the first target 412 is in an anodic phase. A second reactive source 422 is positioned proximate to the second target 414. The second reactive source 422 is configured to generate reactive species proximate to the substrate 402 when the second target 414 is in an anodic phase.

A controller 424 is coupled to the feed gas source 418, the power supply 416, the first 420 and second reactive sources 422, the pump 426, and the drive mechanism 411. The controller 424 is capable of independently controlling these components. For example, the controller 424 can control the speed at which the substrate 402 moves relative to the first 412 and the second targets 414. The controller 424 can send control signals to the power supply 416 to vary the pulse width, voltage level, output current, frequency, polarity and/or other characteristics of the power supply 416. Additionally, the controller 424 can control the state of the first 420 and the second reactive sources 422. In one embodiment, the controller 424 controls the pressure in the chamber 408 by controlling vacuum pump 426. The controller 424 can also control the flow of the feed gas from the feed gas source 418.

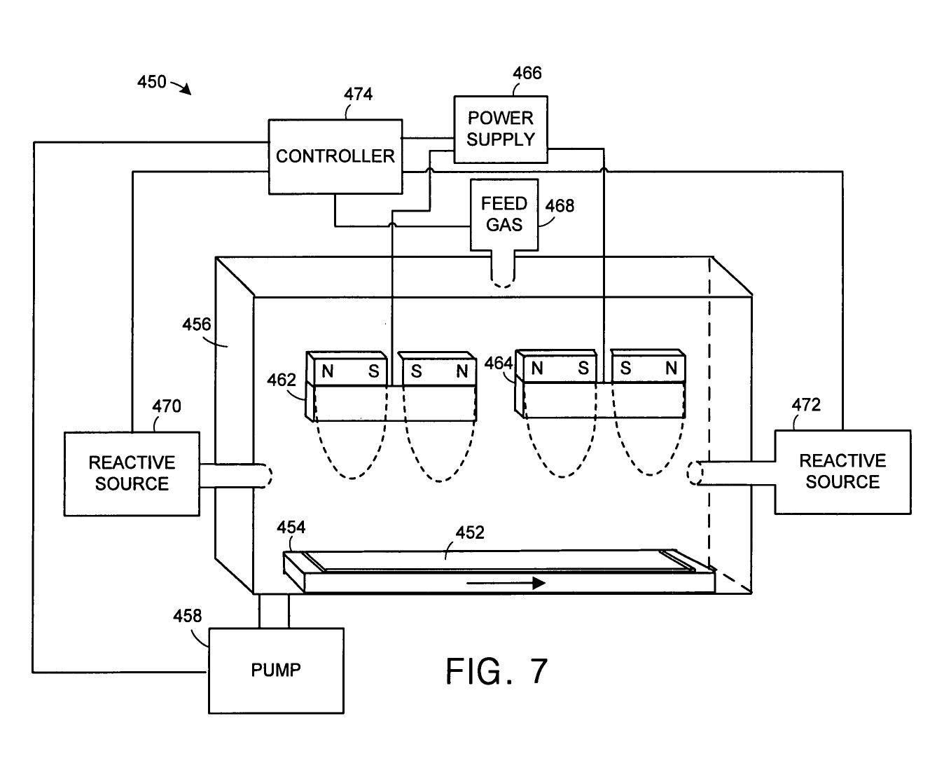

FIG. 7 illustrates a block diagram of an in-line coater 450 with a dual magnetron sputtering system according to another embodiment of the invention. An in-line coating chamber is commonly used for the manufacturing of coated plate glass. In this embodiment, a substrate 452 embodies a sheet of plate glass, such as an architectural window. The substrate 452 can be loaded on belt 454 inside a chamber 456. The belt 454 is designed to move the substrate through the chamber 456. In one embodiment, the substrate 452 is loaded on rollers (not shown). A vacuum pump 458 creates the appropriate pressure in the chamber 456.

The in-line coater 450 also includes a first target 462 and a second target 464 that are coupled to a power supply 466. A feed gas source 468 provides feed gas proximate to the first 462 and the second targets 464. The power supply 466 supplies a voltage between the first 462 and second target 464 to create a plasma from the feed gas. In other embodiments, a separate plasma ionization system (not shown) can be used to start the plasma.

A first reactive source 470 is positioned proximate to the first target 462. The first reactive source 470 is configured to generate reactive species proximate to the substrate 452 when the first target 462 is in an anodic phase. A second reactive source 472 is positioned proximate to the second target 464. The second reactive source 472 is configured to generate reactive species proximate to the substrate 452 when the second target 464 is in an anodic phase. In one embodiment, the first 470 and the second reactive sources 472 are angled towards the substrate 452.

A controller 474 is coupled to the feed gas source 468, the power supply 466, and the first 470 and second reactive sources 472. The controller 474 is capable of independently controlling these components. For example, the controller 474 can send control signals to the power supply 466 to vary the pulse width, voltage level, polarity, output current, frequency and/or other characteristics of the power supply 466. Additionally, the controller 474 can control the state of the first 470 and the second reactive sources 472. In one embodiment, the controller 474 controls the pressure in the chamber 456 and the flow of the feed gas from the feed gas source 468.

While the invention has been particularly shown and described with reference to specific preferred embodiments, it should be understood by those skilled in the art that various changes in form and detail may be made therein without departing from the spirit and scope of the invention as defined herein. For example, although the systems and techniques are described primarily using alternating current (AC) power supplies, the systems and techniques are also applicable to other power supplies, such as pulsed direct current (DC) power supplies or switched direct current (DC) power supply, for example. In addition, although certain examples of reactive sources are described, the systems and techniques may be used in connection with other reactive sources, such as ion sources.

The reactive sources can be pulsed sources. Accordingly, other embodiments are within the scope of the following claims.

What is claimed is:

1. A sputtering apparatus comprising:
a chamber for containing a plasma;
a first and a second target that are positioned in the chamber proximate to a substrate, the first and the second targets comprising at least one type of target material;
a power supply that is coupled to the first and the second targets, the power supply supplying power to the first and the second targets such that when the first target sputters target material, the second target becomes anodic and when the second target sputters target material, the first target becomes anodic; and
a reactive source that supplies reactive species proximate to the substrate, the reactive species being supplied in synchronization with the power supplied to the first and the second targets, the reactive species combining with the sputtered target material to generate a sputtered film on the substrate.

2. The apparatus of claim 1 wherein the power supply comprises a mode of operation in which at least one of the first and the second targets is non-sputtering for a period of time.

3. The apparatus of claim 1 further comprising a controller that controls the synchronization of the reactive source.

4. The apparatus of claim 1 wherein the reactive source comprises a pulsed ion source.

5. The apparatus of claim 1 wherein the reactive source supplies reactive species proximate to the substrate when at least one of the first and the second targets becomes anodic.

6. The apparatus of claim 5 wherein one of the first and the second targets repels the reactive species when the one of the first and the second targets becomes anodic.

7. The apparatus of claim 1 wherein the power supply is chosen from the group comprising an alternating current (AC) power supply, a switched direct current (DC) power supply, and a pulsed DC power supply.

8. The apparatus of claim 1 wherein the reactive source comprises one of an oxygen source, a nitrogen source, and a carbon source.

9. The apparatus of claim 1 wherein the sputtered target material is completely reacted by the reactive species.

10. The apparatus of claim 1 wherein the sputtered target material is partially reacted by the reactive species.

11. The apparatus of claim 1 further comprising an electron source that supplies electrons proximate to at least one of the first and the second targets.

12. The apparatus of claim 1 wherein at least one of the first and the second targets comprises target material that is chosen from the group comprising silicon, zirconium, niobium, tantalum, titanium, and aluminum.

13. The apparatus of claim 1 wherein the plasma is generated from an argon feed gas.

14. The apparatus of claim 1 wherein the substrate is chosen from the group comprising a silicon wafer, a lens, a plastic sheet, a glass plate, and a flexible material.

15. A method for sputtering target material, the method comprising:
ionizing a feed gas to generate a plasma proximate to at least one of a first and a second target;
supplying power to the first and the second targets such that when the first target sputters target material, the second target becomes anodic and when the second target sputters target material, the first target becomes anodic; and
supplying reactive species proximate to a substrate in synchronization with the power supplied to the first and the second targets, the reactive species combining with the sputtered target material to generate a sputtered film on the substrate.

16. The method of claim 15 wherein supplying power to the first and the second targets further comprises supplying power such that at least one of the first and the second targets is non-sputtering for a period of time.

17. The method of claim 15 further comprising supplying the reactive species in a pulsed manner.

18. The method of claim 15 further comprising supplying the reactive species proximate to the substrate when at least one of the first and the second targets becomes anodic.

19. The method of claim 15 wherein supplying the power comprises supplying one of alternating current (AC) power, switched direct current (DC) power, and pulsed DC power.

20. The method of claim 15 wherein supplying the reactive species comprises supplying one of oxygen ions and nitrogen ions.

21. The method of claim 15 further comprising supplying electrons proximate to at least one of the first and the second targets.

22. The method of claim 15 wherein the sputtered target material is completely reacted by the reactive species.

23. The method of claim 15 wherein the sputtered target material is partially reacted by the reactive species.

24. A sputtering apparatus comprising:
means for ionizing a feed gas to generate a plasma proximate to at least one of a first and a second target;
means for supplying power to the first and the second targets such that when the first target sputters target material, the second target becomes anodic and when the second target sputters target material, the first target becomes anodic; and
means for supplying reactive species proximate to a substrate in synchronization with the power supplied to the first and the second targets, the reactive species combining with the sputtered target material to generate a sputtered film on the substrate.
